(19) United States
(12) Patent Application Publication
(10) Pub. No.: US 2021/0242879 A1
(43) Pub. Date: Aug. 5, 2021

(54) TRANSMISSION APPARATUS, TRANSMISSION METHOD, RECEPTION APPARATUS, AND RECEPTION METHOD

(71) Applicant: SONY CORPORATION, Tokyo (JP)

(72) Inventor: Gen ICHIMURA, Tokyo (JP)

(73) Assignee: SONY CORPORATION, Tokyo (JP)

(21) Appl. No.: 17/049,810

(22) PCT Filed: May 15, 2019
(86) PCT No.: PCT/JP2019/019412

§ 371 Date: Oct. 22, 2020

(30) Foreign Application Priority Data
May 23, 2018 (JP) 2018-098383

(51) Int. Cl. H03M 7/50; H03G 7/00; H03M 7/36; G10L 19/00

(52) U.S. Cl. CPC H03M 7/50; H03G 7/007; G10L 2019/0001; G10L 19/00; H03M 7/3044

(57) ABSTRACT

A plurality of types of audio signals is satisfactorily transmitted. An audio signal of each block including a plurality of frames is sequentially transmitted via a predetermined transmission line to a reception side. The audio signal in each of the blocks is a mixed signal of a plurality of types of audio signals. For example, the plurality of types of audio signals includes a plurality of types of compressed audio signals. In this case, for example, the plurality of types of compressed audio signals varies in a transfer speed or a codec. Furthermore, for example, the plurality of types of audio signals includes a compressed audio signal and a linear PCM signal.

### TECHNICAL FIELD

The present technology relates to a transmission apparatus, a transmission method, a reception apparatus, and a reception method.

### BACKGROUND ART

The transmission of a linear PCM signal according to IEC 60958 as a digital audio interface has been widely used. For example, Patent Document 1 includes a description relating to IEC 60958. Furthermore, IEC 61937 according to which a compressed audio signal is transmitted on the IEC 60958 protocol has also spread, and is used in various types of audio codec transmission.

These have been commercially used by mapping the IEC 60958 protocol to the formats of a coaxial terminal and an optical out terminal that are called Sony Philips Digital Interface (SPDIF) in actual products, and High-Definition Multimedia Interface (HDMI), Mobile High-definition Link (MHL), and DisplayPort that are a multimedia interface including a video.

### CITATION LIST

### Patent Document

### Patent Document 1: Japanese Patent Application Laid-Open No. 2009-130606

### SUMMARY OF THE INVENTION

### Problems to be Solved by the Invention

The form of multimedia content has been increasing to a variety of forms including multimedia content received in a broadcast, multimedia content obtained by reproducing a medium such as a Blu-ray disc, multimedia content streaming-distributed or downloaded via the Internet, and the like. In the content, normally, a compressed audio codec is used, and a technology, such as multiple channels or object audio, that enables high-quality reproduction has been developed.

High digital signal processor (DSP) capability is required to decompress these codecs, or a large number of speakers of 5.1 channels or the like need to be arranged, and a heavy load is applied in decoding and reproduction inside a reproduction machine. Therefore, it has been normal that a codec of a compressed form is transmitted to an audio amplifier via a digital audio interface and reproduction is left to the audio amplifier.

In recent years, there has been content that includes a plurality of types of compressed audio codecs in the market, and in outputting to the outside, it has been requested that any of the plurality of types of compressed audio codecs be selected and be output. At this time, if an attempt is made to enable all of the cascade-connected devices to perform reproduction, a common audio codec that can be reproduced, normally, a conventional simple codec, linear PCM 2 channels, or the like, needs to be selected. Furthermore, if it is assumed that sound is reproduced by an audio amplifier but is not reproduced by a television receiver, by using a function such as HDMI, a higher-level compressed audio codec can be output.

As an example of a plurality of types of audio signals, different types of compressed audio codecs have been described above. However, conceivable examples of the plurality of types of audio signals also include a case where data size or data content varies, a case where transfer speed varies, the case of compressed audio and a linear PCM, a case where linear PCM's are different in the number of channels, and the like.

It is an object of the present technology to satisfactorily transmit a plurality of types of audio signals.

### Solutions to Problems

A concept of the present technology is:

a transmission apparatus including:

a transmission unit that sequentially transmits an audio signal in each block via a predetermined transmission line to a reception side, each of the blocks including a plurality of frames,

in which the audio signal in each of the blocks includes a mixed signal of a plurality of types of audio signals.

In the present technology, the transmission unit sequentially transmits the audio signal in each of the blocks including the plurality of frames, via the predetermined transmission line to the reception side. For example, the predetermined transmission line may be a coaxial cable, an optical cable, an Ethernet (IEC 61883-6) cable, an HDMI cable, an MHL cable, or a DisplayPort cable.

The audio signal in each of the blocks is the mixed signal of the plurality of types of audio signals. For example, the plurality of types of audio signals may include a plurality of types of compressed audio signals. In this case, for example, the plurality of types of compressed audio signals may vary in a transfer speed or a codec. Furthermore, for example, the plurality of types of audio signals may include a compressed audio signal and a linear PCM signal. For example, an acquisition unit that acquires the plurality of types of audio signals may be further included.

As described above, in the present technology, an audio signal in each block that serves as a mixed signal of a plurality of types of audio signals is sequentially transmitted via a predetermined transmission line to a reception side. Therefore, the plurality of types of audio signals can be satisfactorily transmitted. In this case, in reproduction of a medium, a plurality of types of audio signals included in content can be simultaneously transmitted. Furthermore, in this case, in the case of reproduction of compressed multichannel content, a compressed multichannel audio signal and the compressed multichannel content can be decoded, a signal that has been down-mixed to 2 channels can be simultaneously transmitted, and switching and use can be performed according to a capability on the reception side. Furthermore, in this case, even in a case where a plurality of applications is operating in a multitasking manner in the transmission apparatus, the plurality of types of audio signals can be transmitted in frames that are different from each other without being mixed. In this case, in a case where the plurality of types of audio signals includes a linear PCM signal, the linear PCM signal can be reproduced with lowest latency on the reception side.

Note that, in the present technology, for example, an information addition unit that adds identification information to the audio signal to be transmitted by the transmission unit may be further included, and the identification information indicates that the audio signal in each of the blocks is a mixed signal of the plurality of types of audio signals. In this case, for example, the information addition unit may add the identification information by using a predetermined bit area of a channel status that is configured in each of the blocks. As described above, by adding the identification information, the reception side can easily recognize that the audio signal in each of the blocks is the mixed signal of the plurality of types of audio signals.

Furthermore, in the present technology, for example, an information addition unit that adds configuration information to the audio signal to be transmitted by the transmission unit may be further included, and the configuration information indicates a configuration of the plurality of types of audio signals. In this case, for example, the information addition unit may add the configuration information by using a predetermined bit area of a channel status that is configured in each of the blocks. As described above, by adding the configuration information, the reception side can easily recognize the configuration of the plurality of types of audio signals.

Furthermore, in the present technology, for example, an information addition unit that adds information relating to a linear PCM signal to the audio signal to be transmitted by the transmission unit when the plurality of types of audio signals includes the linear PCM signal may be further included. In this case, for example, the information addition unit may add the information relating to the linear PCM signal by using user data bits of a predetermined number of consecutive frames. As described above, by adding the information relating to the linear PCM signal, the reception side can appropriately process the linear PCM signal.

Furthermore, another concept of the present technology is:

a reception apparatus including:

a reception unit that sequentially receives an audio signal in each block from a transmission side via a predetermined transmission line, each of the blocks including a plurality of frames,

in which the audio signal in each of the blocks includes a mixed signal of a plurality of types of audio signals.

In the present technology, the reception unit sequentially receives the audio signal in each of the blocks including the plurality of frames, from the transmission side via the predetermined transmission line. The audio signal in each of the blocks is the mixed signal of the plurality of types of audio signals. For example, a processing unit that processes the plurality of types of audio signals and obtains an output linear PCM signal may be further included.

As described above, in the present technology, an audio signal in each block that serves as a mixed signal of a plurality of types of audio signals is sequentially received from a transmission side via a predetermined transmission line. Therefore, the plurality of types of audio signals can be satisfactorily received.

Note that, in the present technology, for example, configuration information indicating a configuration of the plurality of types of audio signals may have been added to the audio signal received by the reception unit, and the processing unit may process the plurality of types of audio signals on the basis of the configuration information. This enables the processing unit to appropriately process the plurality of types of audio signals in accordance with its configuration.

Furthermore, in the present technology, for example, when the plurality of types of audio signals includes a linear PCM signal, information relating to the linear PCM signal may have been added to the audio signal received by the reception unit, and the processing unit may process the linear PCM signal on the basis of the information relating to the linear PCM signal. This enables the processing unit to appropriately process a linear PCM signal on the basis of the information relating to this linear PCM signal.

### Effects of the Invention

According to the present technology, a plurality of types of audio signals can be satisfactorily transmitted. Note that effects described herein are only illustrative and are not restrictive, and additional effects may be exhibited.

### BRIEF DESCRIPTION OF DRAWINGS

FIG. 1 is a block diagram illustrating a configuration example of an AV system serving as an embodiment.

FIG. 2 is a block diagram illustrating a configuration example of an HDMI transmission unit of a BD player and an HDMI reception unit of an audio amplifier.

FIG. 3 is a diagram illustrating periods of various types of transmission data in a case where image data in which width×height is 1920 pixels×1080 lines is transmitted through a TMDS channel.

FIG. 4 is a diagram illustrating pin assignment of an HDMI connector.

FIG. 5 is a diagram illustrating a configuration example of a high-speed bus interface of a television receiver.

FIG. 6 is a diagram illustrating a configuration example of a high-speed bus interface of the audio amplifier.

FIG. 7 is a diagram illustrating a frame configuration according to the IEC 60958 standard.

FIG. 8 is a diagram illustrating a sub-frame configuration according to the IEC 60958 standard.

FIG. 9 is a diagram illustrating a signal modulation scheme according to the IEC 60958 standard.

FIG. 10 is a diagram illustrating channel coding of a preamble according to the IEC 60958 standard.

FIG. 11 is a diagram illustrating the IEC 61937-1 interface format.

FIG. 12 is a diagram schematically illustrating a format of a channel status in a case where a plurality of types of audio signals is simultaneously transmitted.

FIG. 13 is a diagram illustrating an example of a correspondence relationship with a configuration of a plurality of types of audio signals.

FIG. 14 is a diagram illustrating an example of a frame configuration in the case of “48 kHz stream+48 kHz stream”.

FIG. 15 is a diagram illustrating an example of a frame configuration in the case of “48 kHz stream+96 kHz stream”.

FIG. 16 is a diagram illustrating an example of a frame configuration in the case of “48 kHz LPCM stream+48 kHz stream”.

FIG. 17 is a diagram illustrating an example of a user data message.

FIG. 18 is a diagram illustrating an example of information relating to a linear PCM signal.

FIG. 19 is a diagram illustrating an example of a frame configuration in a case where a plurality of types of linear PCM signals is simultaneously transmitted.

FIG. 20 is a block diagram illustrating another configuration example of the AV system.

### MODE FOR CARRYING OUT THE INVENTION

A mode for carrying out the invention (hereinafter referred to as an “embodiment”) is described below. Note that description will be provided in the order described below.

1. Embodiment

2. Variations

### 1. Embodiment

[Configuration Example of AV System]

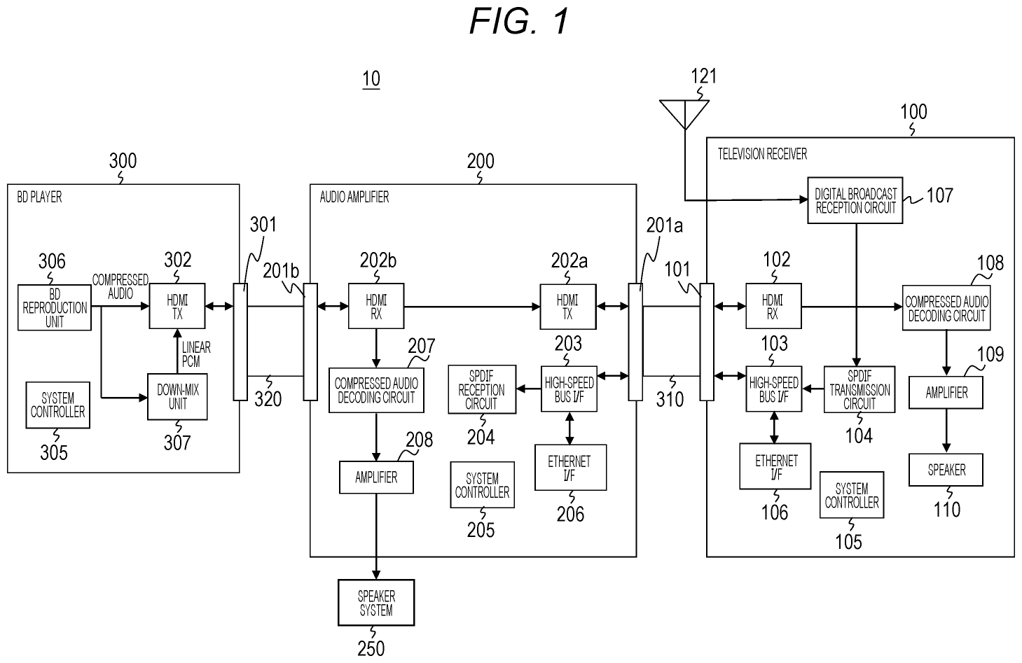

FIG. 1 illustrates a configuration example of an audio/visual (AV) system 10 serving as an embodiment. This AV system 10 includes a Blu-ray disc (BD) player 300 serving as a source device, an audio amplifier 200 serving as a repeater device, and a television receiver 100 serving as a sink device. The audio amplifier 200 is connected to a speaker system 250 for 2 channels or for multiple channels. The television receiver 100 is connected to a reception antenna 121 of a television broadcast. Note that “Blu-ray” is a registered trademark.

The BD player 300 and the audio amplifier 200 are connected via an HDMI cable 320. Note that “HDMI” is a registered trademark. The BD player 300 is provided with an HDMI terminal 301 that is connected to an HDMI transmission unit (HDMI TX) 302. Furthermore, the audio amplifier 200 is provided with an HDMI terminal 201b that is connected to an HDMI reception unit (HDMI RX) 202b. One end of the HDMI cable 320 is connected to the HDMI terminal 301 of the BD player 300, and another end of the HDMI cable 320 is connected to the HDMI terminal 201b of the audio amplifier 200.

Furthermore, the audio amplifier 200 and the television receiver 100 are connected via an HDMI cable 310. The audio amplifier 200 is provided with an HDMI terminal 201a that is connected to an HDMI transmission unit (HDMI RX) 202a and a high-speed bus interface 203 that configures a communication unit. The television receiver 100 is provided with an HDMI terminal 101 that is connected to an HDMI reception unit (HDMI RX) 102 and a high-speed bus interface 103 that configures a communication unit. One end of the HDMI cable 310 is connected to the HDMI terminal 201a of the audio amplifier 200, and another end of the HDMI cable 310 is connected to the HDMI terminal 101 of the television receiver 100.

“Description of BD player”

The BD player 300 includes the HDMI transmission unit 302, a system controller 305, a BD reproduction unit 306, and a down-mix unit 307. The system controller 305 controls operations of respective units of the BD player 300. The BD reproduction unit 306 reproduces content that has been recorded in a Blu-ray disc (BD) serving as a recording medium, outputs a compressed audio signal relating to the recorded content, and transmits the compressed audio signal to the HDMI transmission unit 302. Note that, in the illustrated example, respective units of an image system are appropriately omitted for simplification of description.

In this embodiment, the BD reproduction unit 306 outputs a plurality of types of compressed audio signals. The plurality of types of compressed audio signals is different in a codec, is different in transfer speed, or has the same codec and the same transfer speed but is different in content. Examples of a difference in content include primary sound and secondary sound, a first language and a second language, and the like. Note that a combination of primary sound and an audio description, karaoke, or the like is also conceivable.

The down-mix unit 307 performs decoding and down-mixing processing on a multichannel compressed audio signal, for example, a compressed audio signal of 5.1 channels, 7.1 channels, or the like, that has been output from the BD player 300 to generate a stereo 2-channel linear PCM signal, and transmits the generated signal to the HDMI transmission unit 302.

The HDMI transmission unit 302 sends data of a video (an image) and sound in a baseband from the HDMI terminal 301 to the HDMI cable 320 through communication conforming to HDMI. Here, the HDMI transmission unit 302 generates a digital audio transmission signal according to the IEC 60958 standard (hereinafter referred to as an “SPDIF signal”), maps this SPDIF signal in an audio sample packet, and transmits the SPDIF signal in a forward direction that is the same as a direction of video transmission.

In this embodiment, the HDMI transmission unit 302 transmits a plurality of types of audio signals. In this case, an audio signal in a block of an SPDIF signal is a mixture of a plurality of types of audio signals. Note that details of the SPDIF signal will be described later. Here, the plurality of types of audio signals transmitted by the HDMI transmission unit 302 is all or some of a plurality of compressed audio signals output from the BD reproduction unit 306 and a linear PCM signal obtained by the down-mix unit 307. In the BD player 300, a user can operate a not-illustrated operation unit to set which audio signal the HDMI transmission unit 302 will transmit.

Here, identification information indicating that an audio signal in a block is a mixed signal of a plurality of types of audio signals or configuration information indicating the configuration of the plurality of types of audio signals is added to an SPDIF signal, and when the plurality of types of audio signals includes a linear PCM signal, information relating to the linear PCM signal, or the like is added to the SPDIF signal.

“Description of Audio Player”

The audio amplifier 200 includes the HDMI reception unit 202b, the HDMI transmission unit 202a, the high-speed bus interface 203, an SPDIF reception circuit 204, the system controller 205, an Ethernet interface 206, a compressed audio decoding circuit 207, and an amplifier 208. Note that “Ethernet” is a registered trademark.

The system controller 205 controls operations of respective units of the audio amplifier 200. The HDMI reception unit 202b receives data of an image or sound that has been supplied to the HDMI terminal 201b via the HDMI cable 320 through communication conforming to HDMI. In this case, the HDMI reception unit 202b receives a plurality of types of audio signals that is included in an SPDIF signal that has been transmitted from the BD player 300.

The compressed audio decoding circuit 207 performs decoding processing on an audio signal to be reproduced that has been selected according to a user's operation or automatically from among the plurality of types of audio signals that has been received by the HDMI reception unit 202b, and obtains a 2-channel or multichannel linear PCM signal. The amplifier 208 amplifies a 2-channel or multichannel output linear PCM signal that has been obtained by the compressed audio decoding circuit 207, and supplies the amplified signal to the speaker system 250.

In this case, the compressed audio decoding circuit 207 selectively extracts an audio signal to be reproduced from the SPDIF signal that has been received by the HDMI reception unit 202b, on the basis of configuration information that indicates a configuration of the plurality of types of audio signals and has been added to the SPDIF signal, information that relates to a linear PCM signal and has been added to the SPDIF signal, or the like, and processes the audio signal to be reproduced. Furthermore, in this case, for example, whether or not a linear PCM signal will be determined to be a target to be reproduced can be determined on the basis of the information that relates to the linear PCM signal and has been added to the SPDIF signal, or the like.

Note that, in a case where an audio signal to be reproduced is a linear PCM signal, the compressed audio decoding circuit 207 omits decoding processing. Furthermore, in a case where there is a plurality of audio signals to be reproduced, a linear PCM signal after mixing processing is output. Conceivable examples of a case where there is a plurality of audio signals to be reproduced include a case where primary sound and an audio description are simultaneously reproduced, and the like.

The HDMI transmission unit 202a sends data of a video (an image) and sound in a baseband from the HDMI terminal 201a to the HDMI cable 310 through communication conforming to HDMI. In this case, the HDMI transmission unit 202a transmits one type of audio signal (a compressed audio signal or a linear PCM signal) that has been selected from the plurality of types of audio signals received by the HDMI reception unit 202b and can be handled by the television receiver 100. Here, the HDMI transmission unit 202a generates an SPDIF signal, maps this SPDIF signal in an audio sample packet, and transmits the SPDIF signal in a forward direction that is the same as a direction of video transmission.

The high-speed bus interface 203 is an interface of a bidirectional communication path that is configured by using a reserve line and a hot plug detect (HPD) line that configure the HDMI cable 310. The Ethernet interface 206 is connected to this high-speed bus interface 203. Note that details of the HDMI transmission unit 202a and the high-speed bus interface 203 will be described later. The SPDIF reception circuit 204 is a circuit for receiving an SPDIF signal (a digital audio signal according to the IEC 60958 standard). This SPDIF reception circuit 204 is a reception circuit that conforms to the IEC 60958 standard. This SPDIF reception circuit 204 is provided to receive an audio signal from the television receiver 100 serving as a sink device.

“Description of Television Receiver”

The television receiver 100 includes the HDMI reception unit 102, the high-speed bus interface 103, an SPDIF transmission circuit 104, a system controller 105, an Ethernet interface 106, a digital broadcast reception circuit 107, a compressed audio decoding circuit 108, an amplifier 109, and a speaker 110. Note that, in the illustrated example, respective units of an image system are appropriately omitted for simplification of description.

The system controller 105 controls operations of respective units of the television receiver 100. The HDMI reception unit 102 receives data of an image or sound that has been supplied to the HDMI terminal 101 via the HDMI cable 310 through communication conforming to HDMI. In this case, the HDMI reception unit 202b receives an audio signal included in an SPDIF signal that has been transmitted from the audio amplifier 200. The high-speed bus interface 103 is an interface of the bidirectional communication path that is configured by using the reserve line and the HPD line that configure the HDMI cable 310. The Ethernet interface 106 is connected to this high-speed bus interface 203. Note that details of the HDMI reception unit 102 and the high-speed bus interface 103 will be described later.

The SPDIF transmission circuit 104 is a circuit for transmitting a digital audio transmission signal according to the IEC 60958 standard (hereinafter appropriately referred to as an “SPDIF signal”). This SPDIF transmission circuit 104 is a transmission circuit that conforms to the IEC 60958 standard. This SPDIF transmission circuit 104 is provided to transmit an audio signal to the audio amplifier 200 serving as a repeater device.

The digital broadcast reception circuit 107 processes a television broadcast signal that has been input from the reception antenna 121, and outputs a compressed audio signal relating to broadcast content. In a case where the BD player 300 reproduces content recorded in a BD, the compressed audio decoding circuit 108 performs decoding processing on an audio signal received by the HDMI reception unit 102, and obtains a linear PCM signal. In this case, in a case where the audio signal received by the HDMI reception unit 102 is a linear PCM signal, decoding processing is omitted.

Furthermore, in a case where broadcast content is reproduced, the compressed audio decoding circuit 108 performs decoding processing on a compressed audio signal obtained by the digital broadcast reception circuit 107, and obtains a linear PCM signal. The amplifier 208 amplifies the linear PCM signal obtained by the compressed audio decoding circuit 108, and supplies the amplified signal to the speaker 110. Note that the use of the speaker 110 of this television receiver 100 is canceled in a case where the speaker system 250 is driven in the audio amplifier 200.

“Configuration Example of HDMI Transmission Unit/Reception Unit”

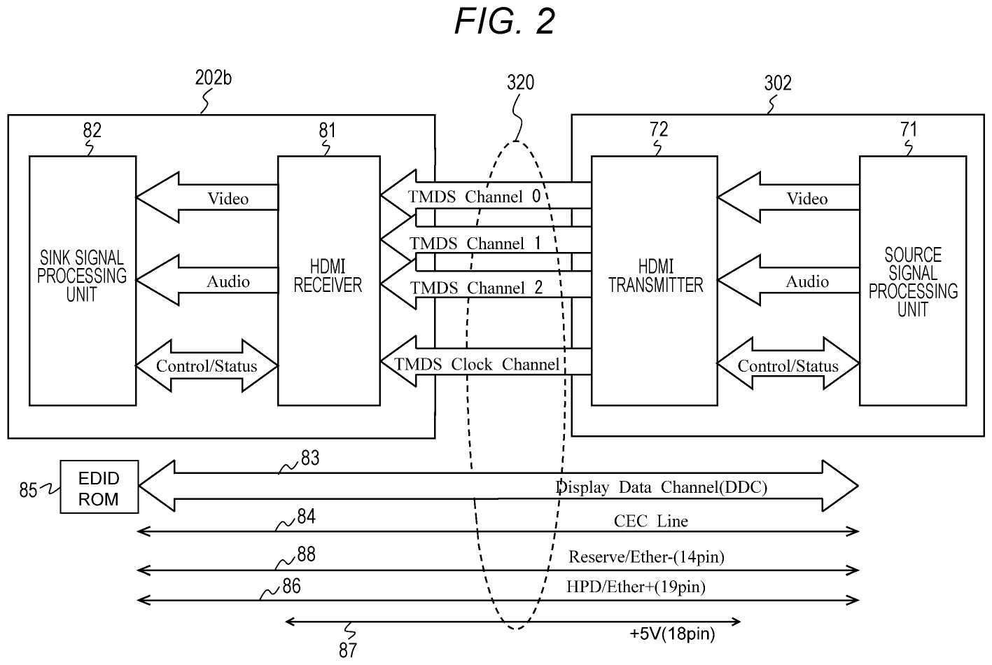

FIG. 2 illustrates a configuration example of the HDMI transmission unit 302 of the BD player 300 and the HDMI reception unit 202b of the audio amplifier 200 in the AV system 10 of FIG. 1. Note that a configuration example of the HDMI transmission unit 202a of the audio amplifier 200 and the HDMI reception unit 102 of the television receiver 100 has a similar configuration, and therefore description is omitted.

During a valid image period (hereinafter appropriately referred to as an “active video period”) that is a period obtained by excluding a horizontal blanking interval and a vertical blanking interval from a period from a certain vertical synchronizing signal to the next vertical synchronizing signal (hereinafter appropriately referred to as a “video field”), the HDMI transmission unit 302 transmits a differential signal of baseband (uncompressed) image data for one screen to the HDMI reception unit 202b through a plurality of channels in one direction. Furthermore, during the horizontal blanking interval and the vertical blanking interval, the HDMI transmission unit 302 transmits a differential signal that corresponds to sound data and a control packet that accompany image data, other auxiliary data, and the like, to the HDMI reception unit 202b through a plurality of channels in one direction.

The HDMI transmission unit 302 includes a source signal processing unit 71 and an HDMI transmitter 72. The source signal processing unit 71 is supplied with baseband uncompressed data of an image (a video) and sound (audio). The source signal processing unit 71 performs required processing on the supplied data of the image and the sound, and supplies the data to the HDMI transmitter 72. Furthermore, the source signal processing unit 71 communicates information for control, information reporting a status (Control/Status), or the like with the HDMI transmitter 72, as needed.

The HDMI transmitter 72 converts image data supplied from the source signal processing unit 71 into a corresponding differential signal, and transmits the corresponding differential signal to the HDMI reception unit 202b that is connected via the HDMI cable 320, through three TMDS channels #0, #1, and #2 serving as a plurality of channels in one direction.

Moreover, auxiliary data of sound data, a control packet, or the like that accompanies uncompressed image data and control data such as a vertical synchronizing signal (VSYNC) or a horizontal synchronizing signal (HSYNC) that have been supplied from the transmitter 72 and the source signal processing unit 71 are converted into corresponding differential signals, and the corresponding differential signals are transmitted to the HDMI reception unit 202b that is connected via the HDMI cable 320, through the three TMDS channels #0, #1, and #2 in one direction.

Furthermore, the transmitter 72 transmits a pixel clock that has been synchronized with image data to be transmitted through the three TMDS channels #0, #1, and #2, through a TMDS clock channel to the HDMI reception unit 202b that is connected via the HDMI cable 320.

The HDMI reception unit 202b receives the differential signal that corresponds to the image data and has been transmitted from the HDMI transmission unit 302 through the plurality of channels in one direction during the active video period, and also receives the differential signal that corresponds to the auxiliary data or the control data and has been transmitted from the HDMI transmission unit 302 through the plurality of channels during the horizontal blanking interval and the vertical blanking interval.

The HDMI reception unit 202b includes an HDMI receiver 81 and a sink signal processing unit 82. The HDMI receiver 81 receives the differential signal corresponding to the image data and the differential signal corresponding to the auxiliary data or the control data that have been transmitted through the TMDS channels #0, #1, and #2 in one direction from the HDMI transmission unit 302 connected via the HDMI cable 320, in synchronization with the pixel clock that has been similarly transmitted from the HDMI transmission unit 302 through the TMDS clock channel. Moreover, the HDMI receiver 81 converts the differential signals into the image data, the auxiliary data, and the control data that correspond to the differential signals, and supplies the image data, the auxiliary data, and the control data to the sink signal processing unit 82, as needed.

The sink signal processing unit 82 performs required processing on data supplied from the HDMI receiver 81, and outputs the data. In addition, the sink signal processing unit 82 communicates information for control, information reporting a status (Control/Status), or the like with the HDMI receiver 81, as needed.

Transmission channels according to HDMI include a display data channel (DDC) 83 and a transmission channel called a CEC line 84 in addition to the three TMDS channels #0, #1, and #2 for serially transmitting image data, auxiliary data, and control data from the HDMI transmission unit 302 to the HDMI reception unit 202b in one direction in synchronization with a pixel clock, and the TMDS clock channel serving as a transmission channel for transmitting the pixel clock.

The DDC 83 includes two not-illustrated lines (signal lines) that are included in the HDMI cable 320, and is used for a source device to read enhanced-extended display identification (E-EDID) from a sink device that is connected via the HDMI cable 320. Stated another way, the sink device includes an EDID ROM 85. The source device reads the E-EDID stored by the EDID ROM 85, via the DDC 83 from the sink device connected via the HDMI cable 320, and recognizes the setting or performance of the sink device on the basis of the E-EDID.

The CEC line 84 includes one not-illustrated line that is included in the HDMI cable 320, and is used to perform bidirectional communication of data for control between the source device and the sink device.

Furthermore, the HDMI cable 320 includes a line 86 that is connected to a pin called hot plug detect (HPD). The source device can detect connection of the sink device, by using the line 86. Furthermore, the HDMI cable 320 includes a line 87 that is used to supply power from the source device to the sink device. Moreover, the HDMI cable 320 includes a reserve line 88.

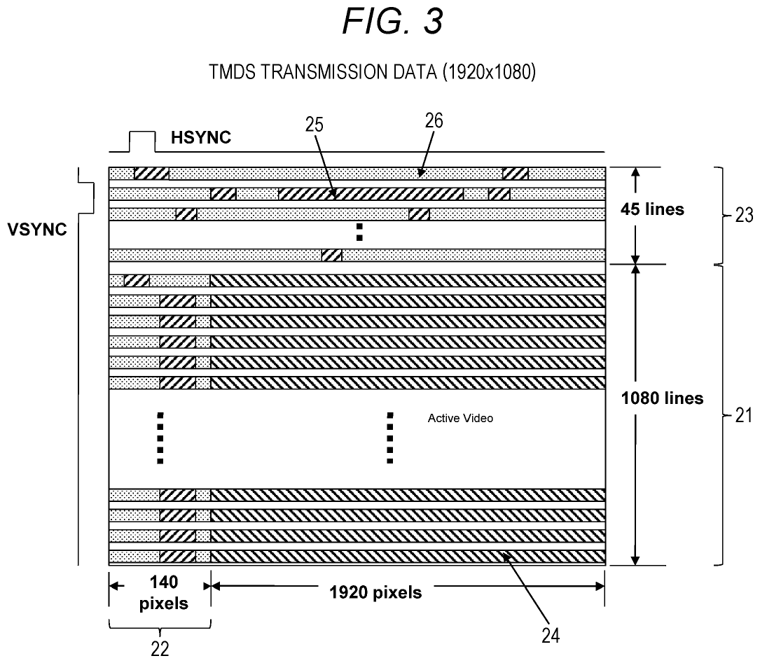

FIG. 3 illustrates periods of various types of transmission data in a case where image data in which width×height is 1920 pixels×1080 lines is transmitted through a TMDS channel. A video field in which transmission data is transmitted through three TMDS channels according to HDMI includes three periods, a video data period 24, a data island period 25, and a control period 26 in accordance with the type of transmission data.

Here, the video field period is a period from an active edge of a certain vertical synchronizing signal to an active edge of the next vertical synchronizing signal, and is divided into a horizontal blanking interval 22 (horizontal blanking), a vertical blanking interval 23 (vertical blanking), and an active pixel period 21 (active video) serving as a period obtained by excluding the horizontal blanking interval and the vertical blanking interval from the video field period.

The video data period 24 is allocated to the active pixel period 21. During this video data period 24, data of an active pixel of 1920 pixels×1080 lines that configures uncompressed image data for one screen is transmitted. The data island period 25 and the control period 26 are allocated to the horizontal blanking interval 22 and the vertical blanking interval 23. During the data island period 25 and the control period 26 that are described above, auxiliary data is transmitted.

Stated another way, the data island period 25 is allocated to portions of the horizontal blanking interval 22 and the vertical blanking interval 23. During this data island period 25, data that does not relate to control from among auxiliary data, for example, a packet of sound data, and the like, is transmitted. The control period 26 is allocated to other portions of the horizontal blanking interval 22 and the vertical blanking interval 23. During this control period 26, data that relates to control from among the auxiliary data, for example, a vertical synchronizing signal, a horizontal synchronizing signal, a control packet, and the like, is transmitted.

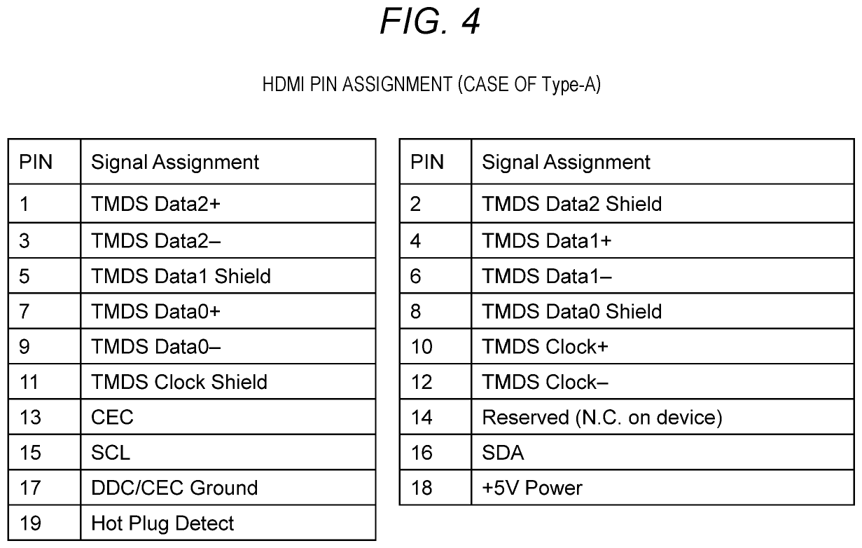

FIG. 4 illustrates pin assignment of an HDMI connector. This pin assignment is an example of type-A. Two lines serving as differential lines through which TMDS Data #i+ and TMDS Data #i− serving as differential signals of TMDS channel #i are transmitted are connected to pines (pins respectively having pin nos. 1, 4, and 7) to which TMDS Data #i+ has been assigned, and pins (pins respectively having pin nos. 3, 6, and 9) to which TMDS Data #i− has been assigned.

Furthermore, the CEC line 84 through which a CEC signal serving as data for control is transmitted is connected to a pin having pin no. 13, and a pin having pin no. 14 is a reserved pin. Furthermore, a line through which a serial data (SDA) signal, such as E-EDID, is transmitted is connected to a pin having pin no. 16, and a line through which a serial clock (SCL) signal serving as a clock signal to be used in synchronization at the time of transmission or reception of the SDA signal is connected to a pin having pin no. 15. The DDC 83 described above is configured by the line through which the SDA signal is transmitted and the line through which the SCL signal is transmitted.

Furthermore, the HPD line 86 that is used for the source device to detect connection of the sink device, as described above, is connected to a pin having pin no. 19. Furthermore, the power line 87 that is used to supply power, as described above, is connected to a pin having pin no. 18.

“Configuration Example of High-Speed Bus Interface”

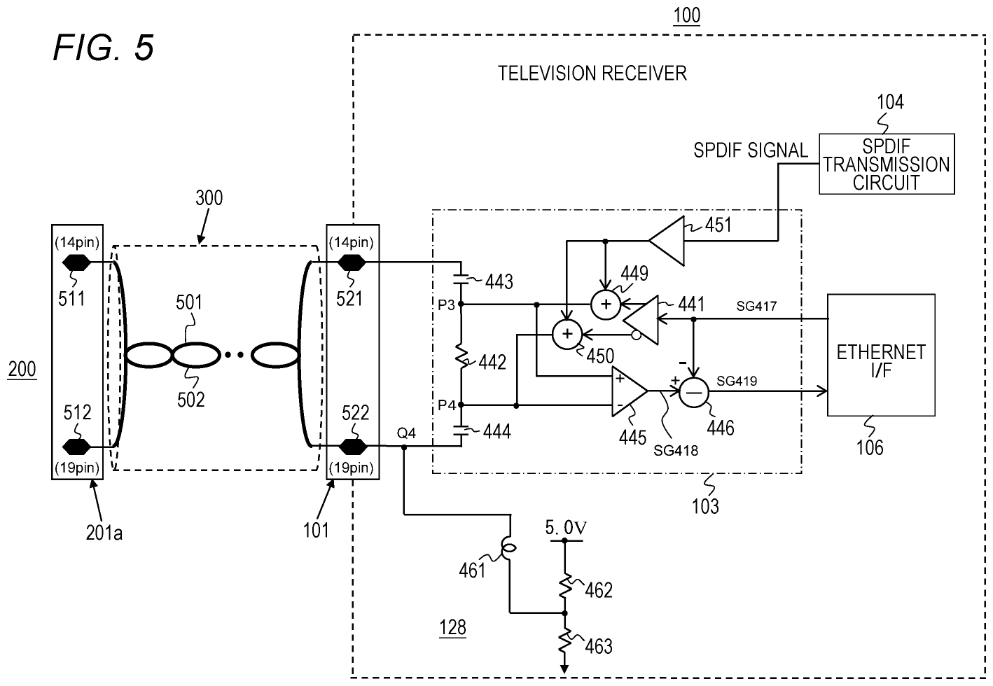

FIG. 5 illustrates a configuration example of the high-speed bus interface 103 of the television receiver 100 in the AV system 10 of FIG. 1. The Ethernet interface 106 performs local area network (LAN) communication, that is, the transmission or reception of an Ethernet signal, by using a transmission line that is configured by a pair of lines, the reserve line and the HPD line, from among a plurality of lines that configures the HDMI cable 310. The SPDIF transmission circuit 104 transmits an SPDIF signal by using the transmission line that is configured by the pair of lines described above.

The television receiver 100 includes a LAN signal transmission circuit 441, a terminating resistor 442, AC coupling capacitances 443 and 444, a LAN signal reception circuit 445, a subtraction circuit 446, addition circuits 449 and 450, and an amplifier 451. These these configure the high-speed bus interface 103. Furthermore, the television receiver 100 includes a choke coil 461, a resistor 462, and a resistor 463 that configure a plug connection transfer circuit 128.

Between a 14-pin terminal 521 and a 19-pin terminal 522 of the HDMI terminal 101, a series circuit of the AC coupling capacitance 443, the terminating resistor 442, and the AC coupling capacitance 444 is connected. Furthermore, between a power line (+5.0 V) and a grounding line, a series circuit of the resistor 462 and the resistor 463 is connected. Then, a mutual connecting point of these resistors 462 and 463 is connected to a connecting point Q4 of the 19-pin terminal 522 and the AC coupling capacitance 444 via the choke coil 461.

A mutual connecting point P3 of the AC coupling capacitance 443 and the terminating resistor 442 is connected to an output side of the addition circuit 449, and is also connected to a positive input side of the LAN signal reception circuit 445. Furthermore, a mutual connecting point P4 of the AC coupling capacitance 444 and the terminating resistor 442 is connected to an output side of the addition circuit 450, and is also connected to a negative input side of the LAN signal reception circuit 445.

One input side of the addition circuit 449 is connected to a positive output side of the LAN signal transmission circuit 441, and an SPDIF signal that has been output from the SPDIF transmission circuit 104 is supplied to another input side of this addition circuit 449 via the amplifier 451. Furthermore, one input side of the addition circuit 450 is connected to a negative output side of the LAN signal transmission circuit 441, and an SPDIF signal that has been output from the SPDIF transmission circuit 104 is supplied to another input side of this addition circuit 450 via the amplifier 451.

A transmission signal (transmission data) SG417 is supplied to an input side of the LAN signal transmission circuit 441 from the Ethernet interface 106. Furthermore, an output signal SG418 of the LAN signal reception circuit 445 is supplied to a positive-side terminal of the subtraction circuit 446, and a transmission signal SG417 is supplied to a negative-side terminal of this subtraction circuit 446. In this subtraction circuit 446, the transmission signal SG417 is subtracted from the output signal SG418 of the LAN signal reception circuit 445, and a reception signal (reception data) SG419 is obtained. In a case where a LAN signal (an Ethernet signal) is transmitted as a differential signal via the reserve line and the HPD line, this reception signal SG419 serves as the LAN signal. This reception signal SG419 is supplied to the Ethernet interface 106.

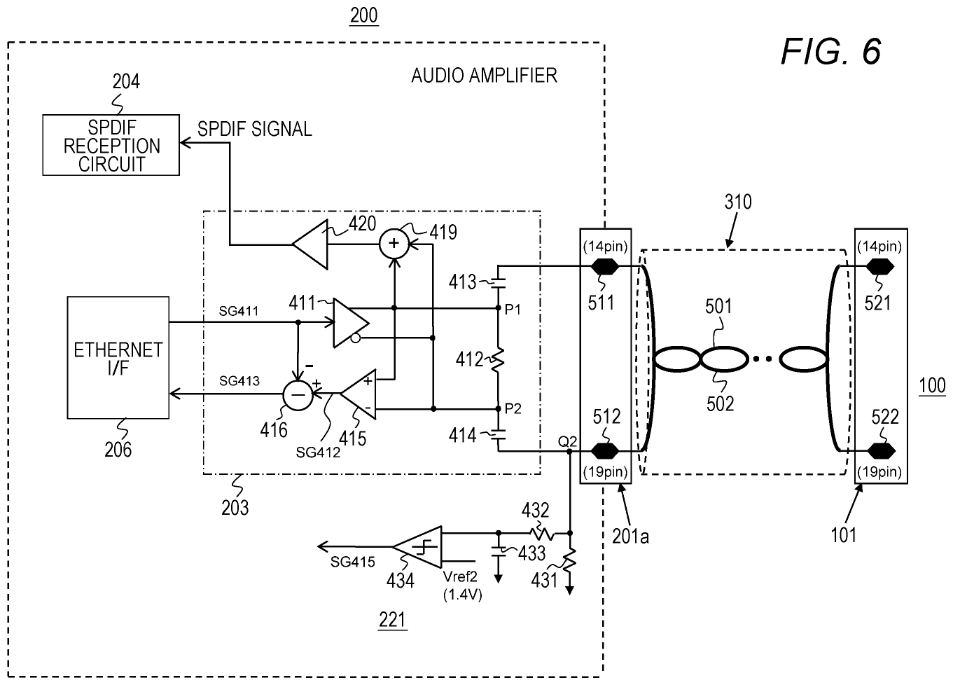

FIG. 6 illustrates a configuration example of the high-speed bus interface 203 of the audio amplifier 200 in the AV system 10 of FIG. 1. The Ethernet interface 206 performs local area network (LAN) communication, that is, the transmission or reception of an Ethernet signal, by using a transmission line that is configured by a pair of lines, the reserve line and the HPD line, from among a plurality of lines that configures the HDMI cable 310. The SPDIF reception circuit 204 receives an SPDIF signal by using the transmission line that is configured by the pair of lines described above.

The audio amplifier 200 includes a LAN signal transmission circuit 411, a terminating resistor 412, AC coupling capacitances 413 and 414, a LAN signal reception circuit 415, a subtraction circuit 416, an addition circuit 419, and an amplifier 420. These configure the high-speed bus interface 203. Furthermore, the audio amplifier 200 includes a pull-down resistor 431, a resistor 432, a capacitance 433, and a comparator 434 that configure a plug connection detection circuit 221. Here, the resistor 432 and the capacitance 433 configure a low-pass filter.

Between a 14-pin terminal 511 and a 19-pin terminal 512 of the HDMI terminal 201a, a series circuit of the AC coupling capacitance 413, the terminating resistor 412, and the AC coupling capacitance 414 is connected. A mutual connecting point P1 of the AC coupling capacitance 413 and the terminating resistor 412 is connected to a positive output side of the LAN signal transmission circuit 411, and is also connected to a positive input side of the LAN signal reception circuit 415.

A mutual connecting point P2 of the AC coupling capacitance 414 and the terminating resistor 412 is connected to a negative output side of the LAN signal transmission circuit 411, and is also connected to a negative input side of the LAN signal reception circuit 415. A transmission signal (transmission data) SG411 is supplied to an input side of the LAN signal transmission circuit 411 from the Ethernet interface 206.

An output signal SG412 of the LAN signal reception circuit 415 is supplied to a positive-side terminal of the subtraction circuit 416, and a transmission signal (transmission data) SG411 is supplied to a negative-side terminal of this subtraction circuit 416. In this subtraction circuit 416, the transmission signal SG411 is subtracted from the output signal SG412 of the LAN signal reception circuit 415, and a reception signal SG413 is obtained. In a case where a LAN signal (an Ethernet signal) is transmitted as a differential signal via the reserve line and the HPD line, this reception signal SG413 serves as the LAN signal. This reception signal SG413 is supplied to the Ethernet interface 206.

A connecting point Q2 of the AC coupling capacitance 414 and the 19-pin terminal 512 is connected to a grounding line via the pull-down resistor 431, and is also connected to a grounding line via a series circuit of the resistor 432 and the capacitance 433. Then, an output signal of the low-pass filter that has been obtained at a mutual connecting point of the resistor 432 and the capacitance 433 is supplied to one input terminal of the comparator 434. In this comparator 434, the output signal of the low-pass filter is compared with a reference voltage Vref2 (+1.4 V) that has been supplied to another input terminal. An output signal SG415 of this comparator 434 is supplied to a not-illustrated control unit (CPU) of the audio amplifier 200.

Furthermore, a mutual connecting point P1 of the AC coupling capacitance 413 and the terminating resistor 412 is connected to one input terminal of the addition circuit 419. Furthermore, a mutual connecting point P2 of the AC coupling capacitance 414 and the terminating resistor 412 is connected to another input terminal of the addition circuit 419. An output signal of this addition circuit 419 is supplied to the SPDIF reception circuit 204 via the amplifier 420. In a case where an SPDIF signal is transmitted as an in-phase signal via the reserve line and the HPD line, the output signal of this addition circuit 419 serves as the SPDIF signal.

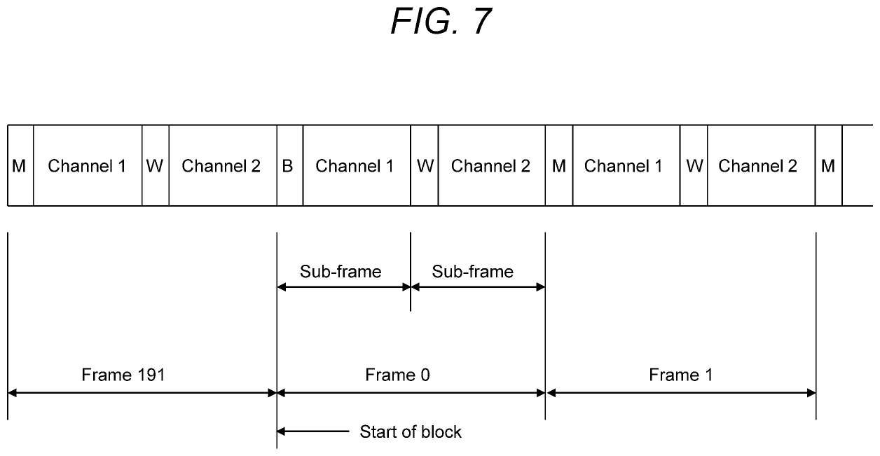

“Details of SPDIF signal” First, the outline of the IEC 60958 standard is described. FIG. 7 illustrates a frame configuration according to the IEC 60958 standard. Each frame is configured by two sub-frames. In the case of 2-channel stereo sound, a left-hand channel signal is included in a first sub-frame, and a right-hand channel signal is included in a second sub-frame.

At the head of a sub-frame, a preamble is provided, as described later, and “M” is given as a preamble to the left-hand channel signal, and “W” is given as a preamble to the right-hand channel signal. However, “B” indicating the start of a block is given to a first preamble every 192 frames. Stated another way, one block is configured by 192 frames. A block is a unit that configures the channel status described later.

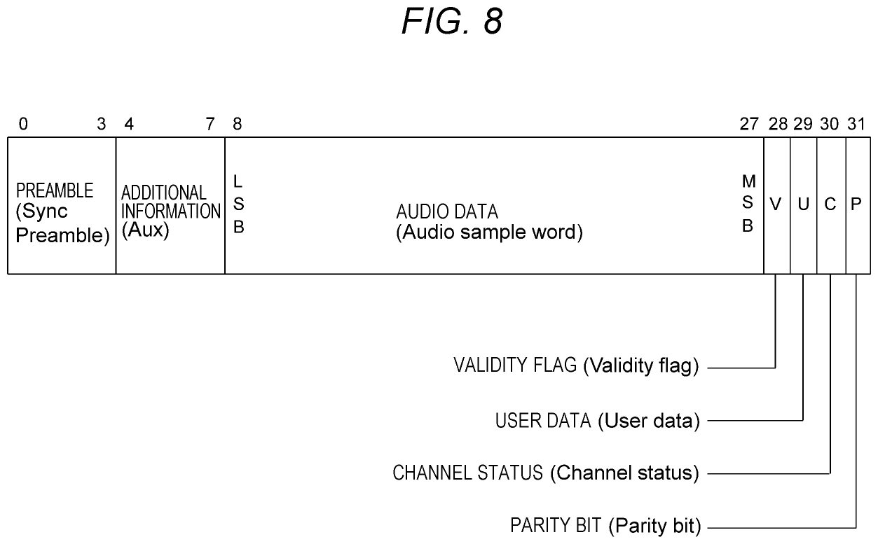

FIG. 8 illustrates a sub-frame configuration according to the IEC 60958 standard. A sub-frame is configured by 32 time slots, 0th to 31st time slots. The 0th to 3rd time slots indicate a preamble (sync preamble). This preamble indicates any of “M”, “W”, and “B” in order to indicate a distinction between left-hand and right-hand channels or a start position of a block, as described above.

4th to 27th time slots are a main data field, and the entirety indicates audio data in a case where a 24-bit code range is employed. Furthermore, in a case where a 20-bit code range is employed, 8th to 27th time slots indicate audio data (audio sample word). In the latter case, 4th to 7th time slots can be used as additional information (auxiliary sample bits). The illustrated example indicates the latter case.

A 28th time slot is a validity flag of the main data field. A 29th time slot indicates one bit of user data. By accumulating this 29th time slot of each of the frames, a series of user data can be configured. A message of this user data is configured with 8-bit information unit (IU) as a unit, and one message includes 3 to 129 information units.

0 to 8 bits of “0” can exist between information units. The head of an information unit is identified by the start bit “1”. In a message, first 7 information units are reserved, and a user can set arbitrary information in an 8th information unit and information units that follow. Messages are divided by 8 or more bits of “0”.

A 30th time slot indicates one bit of a channel status. By accumulating the 30th time slot of each of the frames of each block, a series of channel status can be configured. Note that the head position of a block is indicated by the preamble “B” (the 0th to 3rd time slots), as described above.

A 31st time slot is a parity bit. This parity bit is given in such a way that the numbers of “0”s and “1”s that are included in the 4th to 31st time slots are even numbers.

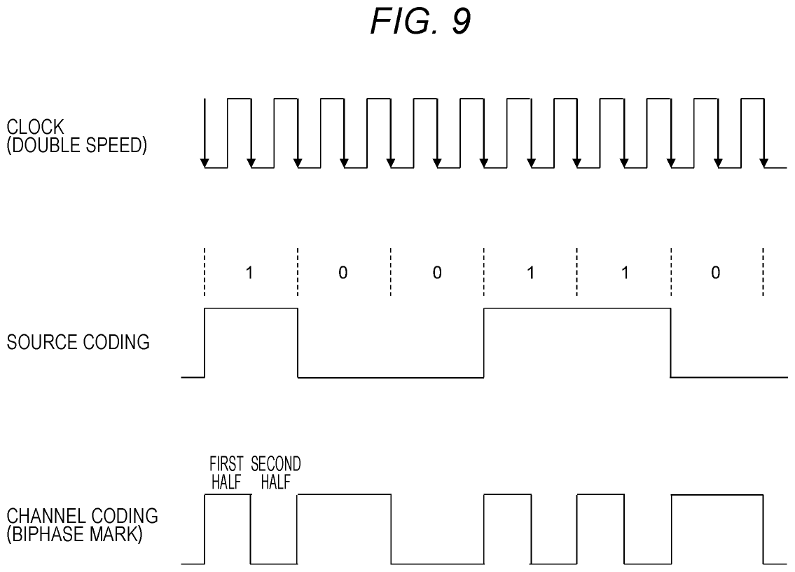

FIG. 9 illustrates a signal modulation scheme according to the IEC 60958 standard. Biphase mark modulation is performed on 4th to 31st time slots obtained by excluding a preamble from a sub-frame. In this biphase mark modulation, a clock having twice the speed of an original signal (source coding) is used. When a clock cycle of an original signal is divided into a first half and a second half, an output of biphase mark modulation is always reversed at an edge of the first half of the clock cycle. Furthermore, at an edge of the second half of the clock cycle, the output is reversed when the original signal indicates “1”, and the output is not reversed when the original signal indicates “0”. Therefore, a clock component in the original signal can be extracted from a signal after biphase mark modulation.

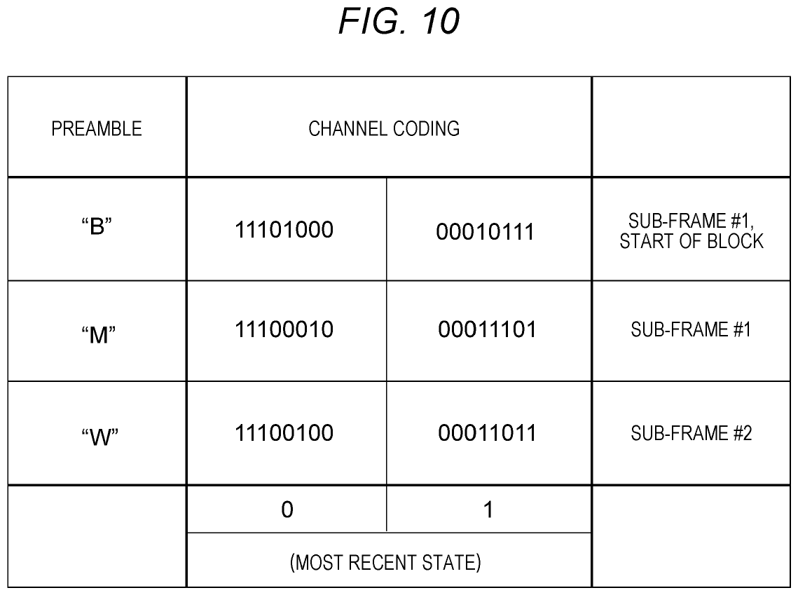

FIG. 10 illustrates channel coding of a preamble according to the IEC 60958 standard. As described above, biphase mark modulation is performed on 4th to 31st time slots of a sub-frame. On the other hand, normal biphase mark modulation is not performed on a preamble of 0th to 3rd time slots, and the preamble is treated as a bit pattern that is synchronized with a double-speed clock. Stated another way, by allocating two bits to each time slot of the 0th to 3rd time slots, an 8-bit pattern, as illustrated, is obtained.

If the most recent state is “0”, “11101000” is allocated to the preamble “B”, “11100010” is allocated to “M”, and “1100100” is allocated to “W”. In contrast, if the most recent state is “1”, “00010111” is allocated to the preamble “B”, “00011101” is allocated to “M”, and “00011011” is allocated to “W”.

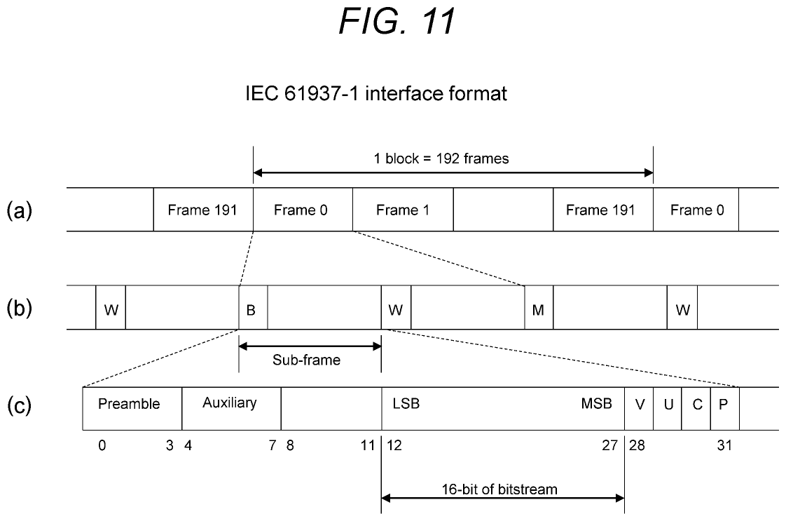

A format of transmitting a compressed audio signal on a protocol according to the IEC 60958 standard is specified by the IEC 61937-1 standard. FIG. 11 illustrates the IEC 61937-1 interface format. FIG. 11(a) illustrates a frame configuration. 192 frames configure one block, and the blocks are consecutive. FIG. 11(b) illustrates that each of the frames includes two sub-frames.

A preamble is provided at the head of a sub-frame, and “B” indicating the start of a block is given to a preamble of a first sub-frame of a block. Then, “W” and “M” are alternately given to first preambles of respective sub-frames that follow.

FIG. 11(c) illustrates a sub-frame configuration. In the case of an SPDIF signal including compressed audio signals of a predetermined number of channels, a bit stream of a compressed audio signal is divided and is sequentially inserted into 14th to 27th time slots of each sub-frame. Stated another way, in a 24-bit audio data area in 4th to 27th time slots of each of the sub-frames, higher-order 16 bits are used to transmit a compressed audio signal.

In this embodiment, the HDMI transmission unit 302 of the BD player 300 transmits a plurality of types of audio signals to the audio amplifier 200. In this case, an audio signal in a block of an SPDIF signal is a mixture of a plurality of types of audio signals. As described above, identification information indicating that an audio signal in a block is a mixture of a plurality of types of audio signals or configuration information indicating a configuration of the plurality of types of audio signals is added to an SPDIF signal, and when the plurality of types of audio signals includes a linear PCM signal, information relating to the linear PCM signal, or the like is added to the SPDIF signal.

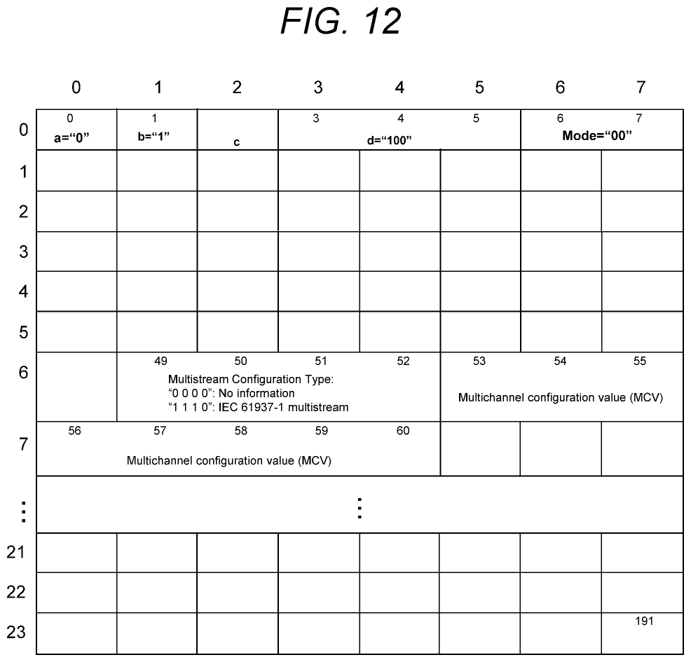

In this embodiment, the identification information and the configuration information are added by using a channel status bit. FIG. 12 schematically illustrates a format of a channel status in a case where a plurality of types of audio signals is simultaneously transmitted. The entirety of a channel status includes 0th to 23rd bytes. ‘a=“0”’ of a 0th bit indicates that this channel status is consumer use. Furthermore, ‘b=“1”’ of a 1st bit indicates use in the transmission of a compressed digital audio signal, similarly to the IEC 61937-1 interface format.

Note that 3 bits, a 3rd bit to a 5th bit, are “000” in the conventional IEC 61937-1 interface format, but another value is used in order to identify a difference in a mode from this conventional IEC 61937-1 interface format. In the illustrated example, “100” is used.

4 bits, a 49th bit to a 52nd bit, are “0000” in the conventional IEC 61937-1 interface format. However, a value that is different from this is set, and serves as identification information indicating that an audio signal in a block is a mixed signal of a plurality of types of audio signals. In the illustrated example, “1110” is used. Furthermore, when these 4 bits, the 49th bit to the 52nd bit, indicate a mixed signal, 8 bits that follow, a 53rd bit to a 60th bit, are enabled.

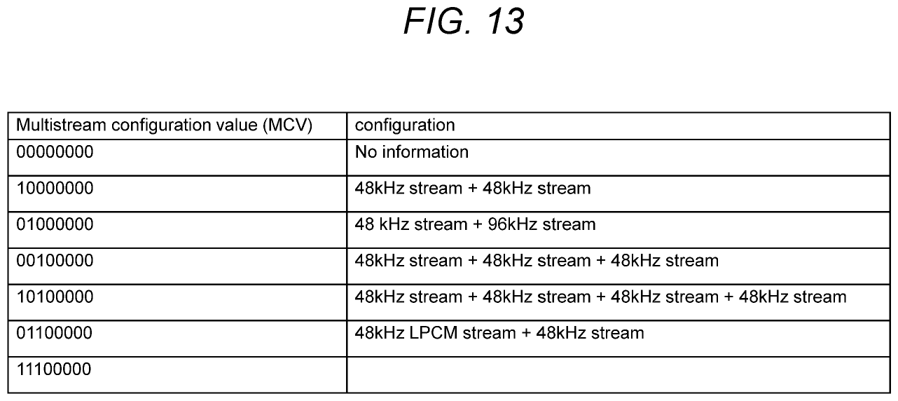

These 8 bits are configuration information indicating a configuration of a plurality of types of audio signals. FIG. 13 illustrates an example of a correspondence relationship between a value of a “multichannel configuration value (MCV)” of the 8 bits, the 53rd bit to the 60th bit, and a configuration of a plurality of types of audio signals. For example, “10000000” indicates a configuration of “48 kHz stream+48 kHz stream”, that is, a configuration that includes two types of compressed audio signals each having a transfer rate of 48 kHz.

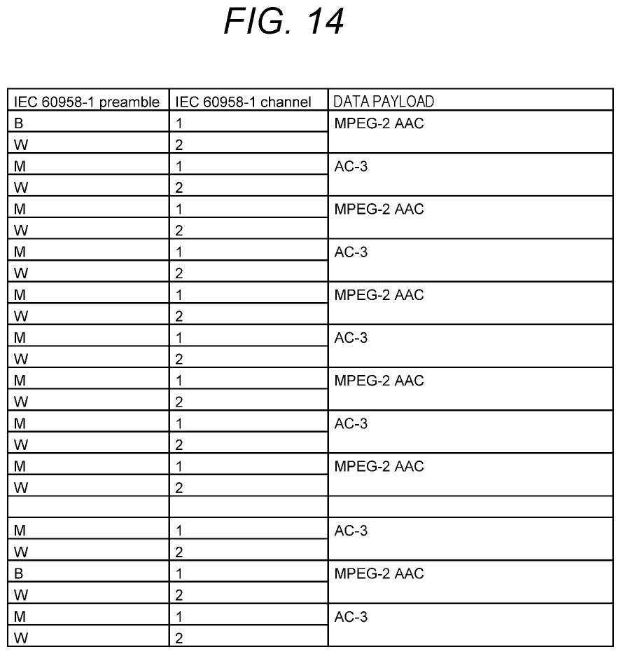

FIG. 14 illustrates an example of a frame configuration in this case. In this case, two types of compressed audio signals are alternately included in each frame with Preamble B (the start of a block) as a starting point. In this case, the entire transfer rate is 96 kHz. In the illustrated example, one codec is “MPEG-2 AAC”, and another codec is “AC-3”. However, this is not restrictive.

Furthermore, for example, “01000000” indicates a configuration of “48 kHz stream+96 kHz stream”, that is, a configuration that includes two types of compressed audio signals respectively having a transfer rate of 48 kHz and a transfer rate of 96 kH.

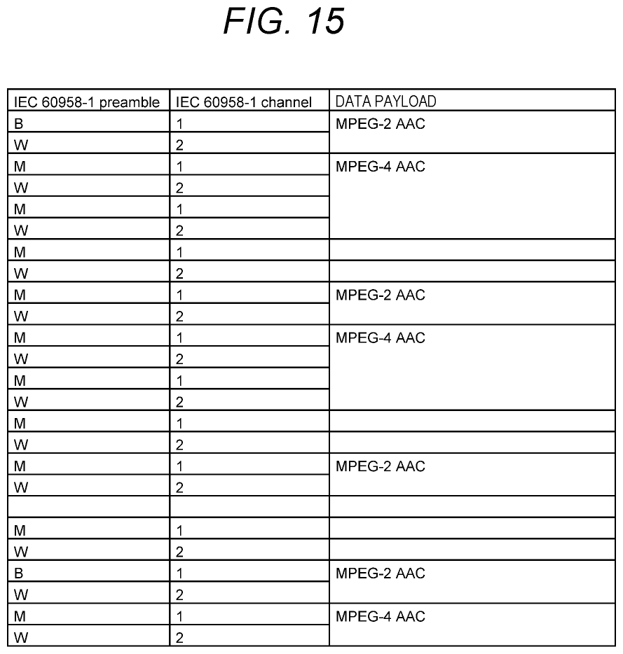

FIG. 15 illustrates an example of a frame configuration in this case. In this case, switching is performed in such a way that one frame including a compressed audio signal having a transfer rate of 48 kHz, two frames including a compressed audio signal having a transfer rate of 96 kH, and one frame of a remainder are repeated with Preamble B (the start of a block) as a starting point. In this case, the entire transfer rate is 192 kHz. In the illustrated example, a codec of the compressed audio signal having a transfer rate of 48 kHz is “MPEG-2 AAC”, and a codec of the compressed audio signal having a transfer rate of 96 kH is “MPEG-4 AAC”. However, this is not restrictive.

Furthermore, for example, “00100000” indicates a configuration of “48 kHz stream+48 kHz stream+48 kHz stream”, that is, a configuration that includes three types of compressed audio signals each having a transfer rate of 48 kHz. In this case, switching is performed in such a way that one frame including a first compressed audio signal, one frame including a second compressed audio signal, one frame including a third compressed audio signal, and one frame of a remainder are repeated, but this is not illustrated. In this case, the entire transfer rate is 192 kHz.

Furthermore, for example, “10100000” indicates a configuration of “48 kHz stream+48 kHz stream+48 kHz stream+48 kHz stream”, that is, a configuration that includes four types of compressed audio signals each having a transfer rate of 48 kHz. In this case, switching is performed in such a way that one frame including a first compressed audio signal, one frame including a second compressed audio signal, one frame including a third compressed audio signal, and one frame including a fourth compressed audio signal are repeated, but this is not illustrated. In this case, the entire transfer rate is 192 kHz.

Furthermore, for example, “01100000” indicates a configuration of “48 kHz LPCM stream+48 kHz stream”, that is, a configuration that includes two types of signals, a linear PCM signal having a transfer rate of 48 kHz and a compressed audio signal having a transfer rate of 48 kHz.

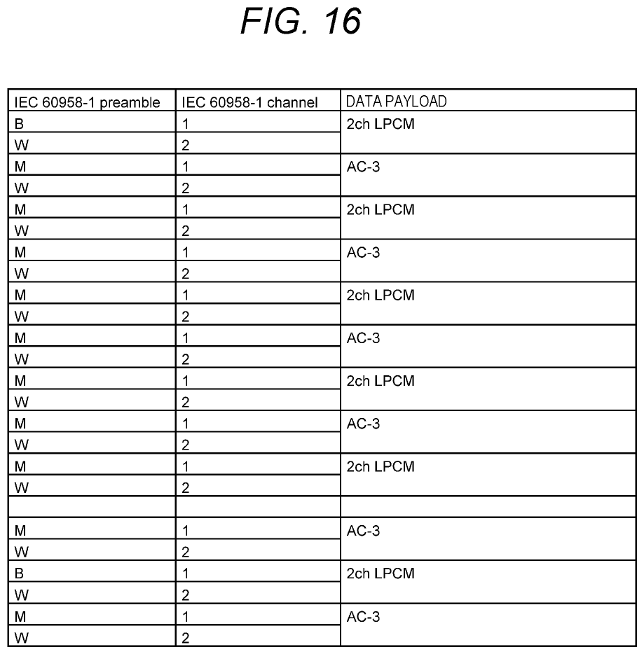

FIG. 16 illustrates an example of a frame configuration in this case. In this case, two types of audio signals are alternately included in each frame with Preamble B (the start of a block) as a starting point. In this case, the entire transfer rate is 96 kHz. In the illustrated example, a codec of the compressed audio signal is “AC-3”, but this is not restrictive.

Furthermore, in this embodiment, the information relating to a linear PCM signal is added by using user bits of a predetermined number of consecutive frames.

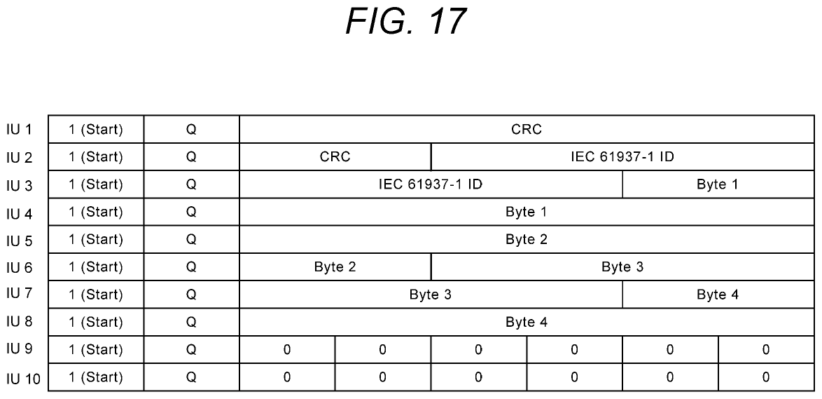

FIG. 17 illustrates an example of a user data message. This user data message is configured by 10 information units (IUs). Identification information of information of “IEC 61937-1 ID” is arranged in a 4th bit to a 0th bit of a 2nd IU and a 5th bit to a 2nd bit of a 3rd IU. Then, an information field of 4 bytes is provided in a 1st bit to a 0th bit of the 3rd IU and a 5th bit to a 0th bit of 4th to 8th IUs. Note that information field is not limited to information field of 4 bytes.

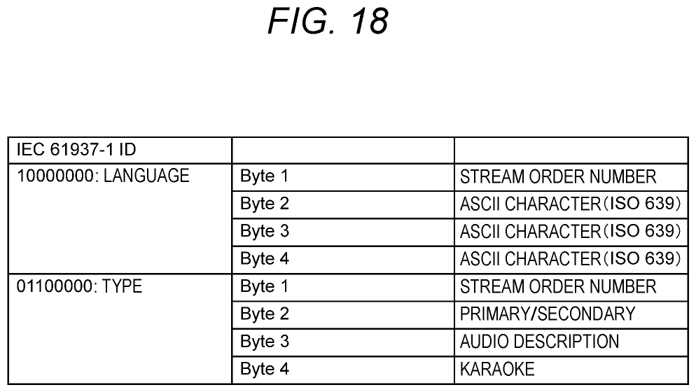

FIG. 18 illustrates an example of information. For example, when “IEC 61937-1 ID” is “10000000”, the language of sound indicated by a linear PCM signal is indicated. A stream order number is arranged in Byte 1. This stream order number is a number that specifies a linear PCM signal that relates to this information. This is because it is assumed that not only one type of linear PCM signal but also a plurality of types of linear PCM signals is transmitted. Furthermore, an ASCII character indicating an abbreviation for the name of a language is arranged in Bytes 2 to 4.

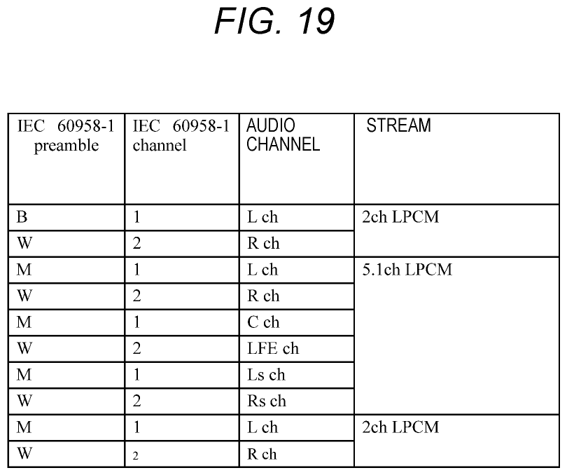

FIG. 19 illustrates an example of a frame configuration in a case where a plurality of types of linear PCM signals is simultaneously transmitted. This example is an example in a case where a stereo 2-channel linear PCM signal and a 5.1-channel linear PCM signal are transmitted. In this case, switching is performed in such a way that one frame of a stereo 2-channel linear PCM signal and three frames including a 5.1-channel linear PCM signal are repeated with Preamble B (the start of a block) as a starting point.

Furthermore, for example, when “IEC 61937-1 ID” is “01100000”, the type of a linear PCM signal is indicated. A stream order number is arranged in Byte 1. Furthermore, information indicating whether the linear PCM signal is a primary audio signal or a secondary audio signal is arranged in Byte 2. Furthermore, information indicating whether or not the linear PCM signal is an audio signal of an audio description is arranged in Byte 3. Information indicating whether or not the linear PCM signal is an audio signal for karaoke is arranged in Byte 4.

Note that the information illustrated in FIG. 18 is merely an example, and is not restrictive. By using the user data message, as illustrated in FIG. 17, various types of information relating to a linear PCM signal can be transmitted to a reception side.

As described above, in the AV system 10 illustrated in FIG. 1, a plurality of types of audio signals can be satisfactorily transmitted from the BD player 300 to an audio player 200, and the audio player 200 can reproduce a multi-sound application. In this case, in a case where a plurality of types of audio signals is reproduced by the BD reproduction unit 306 of the BD player 300, these can be simultaneously transmitted to the audio amplifier 200.

Furthermore, in this case, in a case where a multichannel compressed audio signal is reproduced by the BD reproduction unit 306 of the BD player 300, this multichannel compressed audio signal and a stereo 2-channel linear PCM signal obtained by processing the multichannel compressed audio signal in the down-mix unit 307 can be simultaneously transmitted to the audio amplifier 200, and the multichannel compressed audio signal and the stereo 2-channel linear PCM signal can be switched and used according to the capability of the audio amplifier 200. For example, in a case where the audio player 200 does not correspond to a codec of the multichannel compressed audio signal, the stereo 2-channel linear PCM signal can be used in the audio amplifier 200.

<2. Variations>

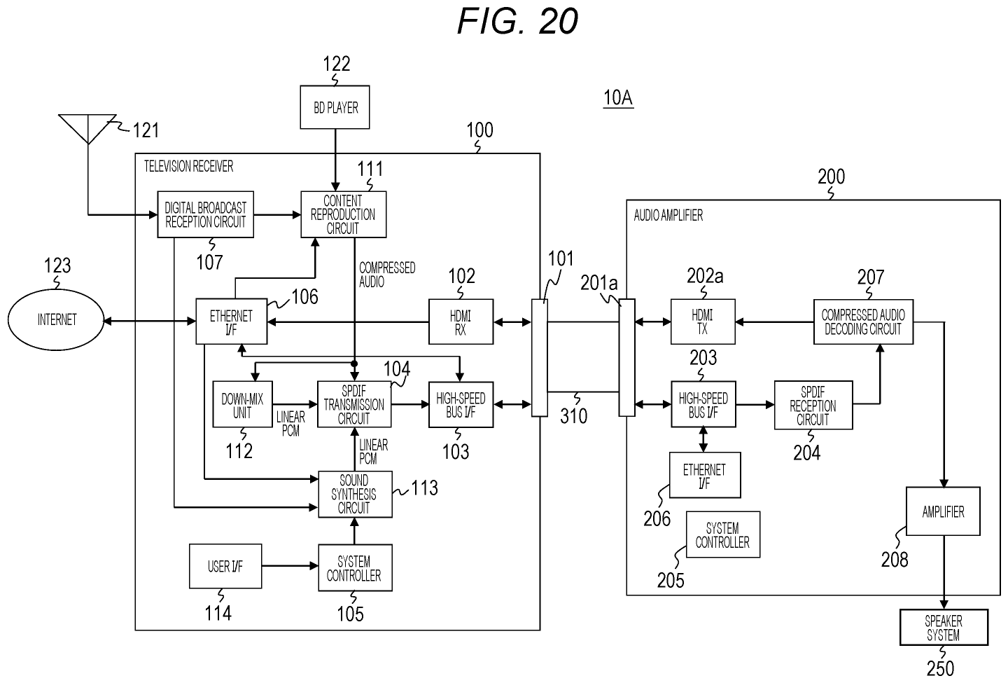

Note that the embodiment described above has indicated an example in which an audio signal is transmitted from the BD player 300 to the audio amplifier 200. However, the present technology can be similarly applied to a case where an audio signal is transmitted from a television receiver 100 to an audio amplifier in an AV system 10A that is configured as illustrated in FIG. 20.

The AV system 10A illustrated in FIG. 20 is briefly described. In FIG. 20, a portion that corresponds to FIG. 1 is illustrated by using the same reference signs, and its detailed description is appropriately omitted. This AV system 10A includes a television receiver 100 and an audio amplifier 200. The television receiver 100 is connected to a reception antenna 121 for a television broadcast, a Blu-ray disc (BD) player 122, and the Internet 123. Furthermore, the audio amplifier 200 is connected to a speaker system 250 for 2 channels or for multiple channels. The television receiver 100 and the audio amplifier 200 are connected via an HDMI cable 310.

The television receiver 100 includes an HDMI reception unit 102, a high-speed bus interface 103, and an SPDIF transmission circuit 104. Furthermore, the television receiver 100 includes a system controller 105, an Ethernet interface 106, a digital broadcast reception circuit 107, a content reproduction circuit 111, a down-mix unit 112, a sound synthesis circuit 113, and a user interface 114. Note that, in the illustrated example, respective units of an image system are appropriately omitted for simplification of description.

The user interface 114 is connected to the system controller 105. This user interface 114 configures an operation unit that a user uses to perform various operations, and includes, for example, a remote controller, a touch panel, a mouse, a keyboard, a gesture input unit that detects an input of an instruction by using a camera, a sound input unit that inputs an instruction by using sound, or the like.

The content reproduction circuit 111 selectively extracts a compressed audio signal of broadcast content that has been obtained by the digital broadcast reception circuit 107, a compressed audio signal of reproduction content that has been supplied from the BD player 122, or a compressed audio signal of Internet content that has been obtained by the Ethernet interface 106, and transmits the extracted compressed audio signal to the SPDIF transmission circuit 104. In this case, a plurality of types of compressed audio signals is supplied from the content reproduction circuit 111 to the SPDIF transmission circuit 104 in some cases. Examples include a case where reproduction content of the BD player 122 includes a plurality of types of compressed audio signals, and the like.

The sound synthesis circuit 113 receives, from the system controller 105, operation sound data that corresponds to an operation performed on the user interface 114, generates a linear PCM signal of operation sound, and transmits the linear PCM signal to the SPDIF transmission circuit 104. Such a linear PCM signal of operation sound requires a real-time property. Furthermore, the sound synthesis circuit 113 receives, from the system controller 105, reporting sound data that reports to a user that an email has been received, generates a linear PCM signal of reporting sound, and transmits the linear PCM signal to the SPDIF transmission circuit 104.

Furthermore, the sound synthesis circuit 113 receives subtitles data from the digital broadcast reception circuit 107, generates a liner PCM signal of subtitles sound by using subtitles reading software, and transmits the linear PCM signal to the SPDIF transmission circuit 104. Such a linear PCM signal of subtitles sound requires a real-time property. Examples include a case where broadcast content is a foreign movie, a language of sound indicated by a compressed audio signal is a foreign language, and subtitles are Japanese subtitles, and other cases. Note that, with regard to this subtitles sound, the similar is applied to a case where subtitles data relating to reproduction content from the BD player 122 rather than broadcast content is present.

Furthermore, the sound synthesis circuit 113 receives text data of translation sound that the Ethernet interface 106 has received from a translation server (not illustrated in FIG. 20), generates a linear PCM signal of the translation sound, and transmits the linear PCM signal to the SPDIF transmission circuit 104.

Here, the Ethernet interface 106 receives, for example, a PCM sound signal of lines in a first language that has been obtained by a compressed audio decoding circuit 207 of the audio amplifier 200, via an HDMI transmission unit 202a of the audio amplifier 200 and the HDMI reception unit 102 of the television receiver 100, and transmits this PCM sound signal of the lines in the first language to the translation server, and therefore the Ethernet interface 106 receives, from the translation server, text data of translation sound of lines in a second language.

The down-mix unit 112 performs decoding and down-mixing processing on a multichannel compressed audio signal that has been extracted by the content reproduction circuit 111 to generate a stereo 2-channel linear PCM signal, and transmits the stereo 2-channel linear PCM signal to the SPDIF transmission circuit 104. This enables the multichannel compressed audio signal and the stereo 2-channel linear PCM signal to be simultaneously transmitted from the SPDIF transmission circuit 104. In this case, which signal will be reproduced is left to a reception side. This is effective in a case where respective reproduction devices having different reproduction performance are present in a plurality of rooms, although the illustrated example only indicates the audio amplifier 200 as a reproduction device on the reception side.

The SPDIF transmission circuit 104 transmits a plurality of types of audio signals. In this case, an audio signal in a block of an SPDIF signal is a mixture of the plurality of types of audio signals (see FIGS. 14 to 16). Here, the plurality of types of audio signals transmitted by the SPDIF transmission circuit 104 includes all or some of a compressed audio signal supplied from the content reproduction circuit 111, a linear PCM signal supplied from the down-mix unit 112, and a linear PCM signal supplied from the sound synthesis circuit 113. A user can operate the user interface 114 to set which audio signal the SPDIF transmission circuit 104 will transmit.

Here, identification information indicating that an audio signal in a block is a mixed signal of a plurality of types of audio signals or configuration information indicating a configuration of the plurality of types of audio signals is added to an SPDIF signal, and when the plurality of types of audio signals includes a linear PCM signal, information relating to the linear PCM signal, or the like is added to the SPDIF signal (see FIGS. 12 and 17).

The audio amplifier 200 includes the HDMI transmission unit 202a, a high-speed bus interface 203, and an SPDIF reception circuit 204. Furthermore, the audio amplifier 200 includes a system controller 205, an Ethernet interface 206, the compressed audio decoding circuit 207, and an amplifier 208.

The compressed audio decoding circuit 207 performs decoding processing on an audio signal to be reproduced that has been selected according to a user's operation or automatically from among a plurality of types of audio signals that has been received by the SPDIF reception circuit 204, and obtains a 2-channel or multichannel linear PCM signal. The amplifier 208 amplifies a 2-channel or multichannel output linear PCM signal that has been obtained by the compressed audio decoding circuit 207, and supplies the amplified signal to the speaker system 250.

In this case, the compressed audio decoding circuit 207 selectively extracts an audio signal to be reproduced from an SPDIF signal that has been received by the SPDIF reception circuit 204, on the basis of configuration information that indicates a configuration of a plurality of types of audio signals and has been added to the SPDIF signal, information that relates to a linear PCM signal and has been added to the SPDIF signal, or the like, and processes the audio signal to be reproduced. Furthermore, in this case, for example, whether or not a linear PCM signal will be determined to be a target to be reproduced can be determined on the basis of the information that relates to the linear PCM signal and has been added to the SPDIF signal, or the like.

Note that, in a case where an audio signal to be reproduced is a linear PCM signal, decoding processing is omitted. Furthermore, in a case where there is a plurality of audio signals to be reproduced, a linear PCM signal after mixing processing is output. Conceivable examples of a case where there is a plurality of audio signals to be reproduced include a case where primary sound and an audio description are simultaneously reproduced, and the like.

In the AV system 10A illustrated in FIG. 20, a plurality of types of audio signals can be satisfactorily transmitted from the television receiver 100 to the audio player 200, and the audio player 200 can reproduce a multi-sound application. In this case, even in a case where a plurality of applications is operating in a multitasking manner in the television receiver 100, the plurality of types of audio signals can be transmitted in frames that are different from each other without being mixed. Furthermore, in this case, in a case where the plurality of types of audio signals includes a linear PCM signal that requires a real-time property, the audio amplifier 200 can reproduce the signal with lowest latency.

Furthermore, the embodiment described above has indicated an example in which an HDMI transmission line or HDMI ARC is used as an IEC 60958 transmission line, but an example is also conceivable in which a coaxial cable or an optical cable is used. Similarly, an example is also conceivable in which an IEC 61883-6 transmission line, an MHL transmission line, a DisplayPort transmission line (a DP transmission line), or the like is used as the IEC 60958 transmission line. In these cases, similarly to a case where the HDMI transmission line is used, an SPDIF signal (an IEC 60958 signal) is mapped in an audio sample packet, and is transmitted in a forward direction that is the same as a direction in video transmission.

Furthermore, a preferred embodiment of the present disclosure has been described in detail with reference to the attached drawings, but the technical scope of the present disclosure is not limited to the examples described above. It is obvious that a person with ordinary skill in the technical field of the present disclosure could conceive a variety of variations or modifications without departing from a technical idea described in the claims, and it should be understood that the variations or modifications fall under the technical scope of the present disclosure.

Furthermore, the technology can also employ the configuration described below.

(1) A transmission apparatus including:

a transmission unit that sequentially transmits an audio signal in each block via a predetermined transmission line to a reception side, each of the blocks including a plurality of frames,

in which the audio signal in each of the blocks includes a mixed signal of a plurality of types of audio signals.

(2) The transmission apparatus described in (1) described above,

in which the plurality of types of audio signals includes a plurality of types of compressed audio signals.

(3) The transmission apparatus described in (2) described above,

in which the plurality of types of compressed audio signals varies in a transfer speed or a codec.

(4) The transmission apparatus described in (1) described above,

in which the plurality of types of audio signals includes a compressed audio signal and a linear PCM signal.

(5) The transmission apparatus described in any of (1) to (4) described above, further including:

an information addition unit that adds identification information to the audio signal to be transmitted by the transmission unit, the identification information indicating that the audio signal in each of the blocks includes the mixed signal of the plurality of types of audio signals.

(6) The transmission apparatus described in (5) described above,

in which the information addition unit adds the identification information by using a predetermined bit area of a channel status that is configured in each of the blocks.

(7) The transmission apparatus described in any of (1) to (6) described above, further including:

an information addition unit that adds configuration information to the audio signal to be transmitted by the transmission unit, the configuration information indicating a configuration of the plurality of types of audio signals.

(8) The transmission apparatus described in (7) described above,

in which the information addition unit adds the configuration information by using a predetermined bit area of a channel status that is configured in each of the blocks.

(9) The transmission apparatus described in any of (1) to (8) described above, further including:

an information addition unit that adds information relating to a linear PCM signal to the audio signal to be transmitted by the transmission unit, when the plurality of types of audio signals includes the linear PCM signal.

(10) The transmission apparatus described in (9) described above,

in which the information addition unit adds the information relating to the linear PCM signal by using user data bits of a predetermined number of consecutive frames.

(11) The transmission apparatus described in any of (1) to (10) described above, further including:

an acquisition unit that acquires the plurality of types of audio signals.

(12) The transmission apparatus described in any of (1) to (11) described above,

in which the predetermined transmission line includes a coaxial cable, an optical cable, an Ethernet (IEC 61883-6) cable, an HDMI cable, an MHL cable, or a DisplayPort cable.

(13) A transmission method including:

a process of sequentially transmitting an audio signal in each block via a predetermined transmission line to a reception side, each of the blocks including a plurality of frames,

in which the audio signal in each of the blocks includes a mixed signal of a plurality of types of audio signals.

(14) A reception apparatus including:

a reception unit that sequentially receives an audio signal in each block from a transmission side via a predetermined transmission line, each of the blocks including a plurality of frames,

in which the audio signal in each of the blocks includes a mixed signal of a plurality of types of audio signals.

(15) The reception apparatus described in (14) described above, further including:

a processing unit that processes the plurality of types of audio signals, and obtains an output linear PCM signal.

(16) The reception apparatus described in (15) described above,

in which configuration information has been added to the audio signal received by the reception unit, the configuration information indicating a configuration of the plurality of types of audio signals, and

the processing unit processes the plurality of types of audio signals on the basis of the configuration information.

(17) The reception apparatus described in (15) or (16) described above,

in which information relating to a linear PCM signal has been added to the audio signal received by the reception unit, when the plurality of types of audio signals includes the linear PCM signal, and

the processing unit processes the linear PCM signal on the basis of the information relating to the linear PCM signal.

(18) A reception method including:

a process of sequentially receiving an audio signal in each block from a transmission side via a predetermined transmission line, each of the blocks including a plurality of frames,

in which the audio signal in each of the blocks includes a mixed signal of a plurality of types of audio signals.

### REFERENCE SIGNS LIST

10, 10A AV system
100 Television receiver
101 HDMI terminal
102 HDMI reception unit
103 High-speed bus interface
104 SPDIF transmission circuit
105 System controller
106 Ethernet interface
107 Digital broadcast reception circuit
108 Compressed audio decoding circuit
109 Amplifier
110 Speaker
111 Content reproduction circuit
112 Down-mix unit
113 Sound synthesis circuit
114 User interface
121 Reception antenna
122 BD player
123 Internet
200 Audio amplifier
201a, 201b HDMI terminal
202a HDMI transmission unit
202b HDMI reception unit
203 High-speed bus interface
204 SPDIF reception circuit
205 System controller
206 Ethernet interface
207 Compressed audio decoding circuit
208 Amplifier
250 Speaker system
300 BD player
301 HDMI terminal
302 HDMI transmission unit
305 System controller
306 BD reproduction unit
310, 320 HDMI cable

1. A transmission apparatus comprising:
a transmission unit that sequentially transmits an audio signal in each block via a predetermined transmission line to a reception side, each of the blocks including a plurality of frames,
wherein the audio signal in each of the blocks includes a mixed signal of a plurality of types of audio signals.

2. The transmission apparatus according to claim 1,
wherein the plurality of types of audio signals includes a plurality of types of compressed audio signals.

3. The transmission apparatus according to claim 2,
wherein the plurality of types of compressed audio signals varies in a transfer speed or a codec.

4. The transmission apparatus according to claim 1,
wherein the plurality of types of audio signals includes a compressed audio signal and a linear PCM signal.

5. The transmission apparatus according to claim 1, further comprising:
an information addition unit that adds identification information to the audio signal to be transmitted by the transmission unit, the identification information indicating that the audio signal in each of the blocks includes the mixed signal of the plurality of types of audio signals.

6. The transmission apparatus according to claim 5,
wherein the information addition unit adds the identification information by using a predetermined bit area of a channel status that is configured in each of the blocks.

7. The transmission apparatus according to claim 1, further comprising:
an information addition unit that adds configuration information to the audio signal to be transmitted by the transmission unit, the configuration information indicating a configuration of the plurality of types of audio signals.

8. The transmission apparatus according to claim 7,
wherein the information addition unit adds the configuration information by using a predetermined bit area of a channel status that is configured in each of the blocks.

9. The transmission apparatus according to claim 1, further comprising:
an information addition unit that adds information relating to a linear PCM signal to the audio signal to be transmitted by the transmission unit, when the plurality of types of audio signals includes the linear PCM signal.

10. The transmission apparatus according to claim 9,
wherein the information addition unit adds the information relating to the linear PCM signal by using user data bits of a predetermined number of consecutive frames.

11. The transmission apparatus according to claim 1, further comprising:
an acquisition unit that acquires the plurality of types of audio signals.

12. The transmission apparatus according to claim 1,
wherein the predetermined transmission line includes a coaxial cable, an optical cable, an Ethernet (IEC 61883-6) cable, an HDMI cable, an MHL cable, or a DisplayPort cable.

13. A transmission method comprising:
a process of sequentially transmitting an audio signal in each block via a predetermined transmission line to a reception side, each of the blocks including a plurality of frames,
wherein the audio signal in each of the blocks includes a mixed signal of a plurality of types of audio signals.

14. A reception apparatus comprising:
a reception unit that sequentially receives an audio signal in each block from a transmission side via a predetermined transmission line, each of the blocks including a plurality of frames,
wherein the audio signal in each of the blocks includes a mixed signal of a plurality of types of audio signals.

15. The reception apparatus according to claim 14, further comprising:
a processing unit that processes the plurality of types of audio signals, and obtains an output linear PCM signal.

16. The reception apparatus according to claim 15,
wherein configuration information has been added to the audio signal received by the reception unit, the configuration information indicating a configuration of the plurality of types of audio signals, and
the processing unit processes the plurality of types of audio signals on a basis of the configuration information.

17. The reception apparatus according to claim 15,
wherein information relating to a linear PCM signal has been added to the audio signal received by the reception unit, when the plurality of types of audio signals includes the linear PCM signal, and
the processing unit processes the linear PCM signal on a basis of the information relating to the linear PCM signal.

18. A reception method comprising:
a process of sequentially receiving an audio signal in each block from a transmission side via a predetermined transmission line, each of the blocks including a plurality of frames,
wherein the audio signal in each of the blocks includes a mixed signal of a plurality of types of audio signals.
